(19) United States
(12) Patent Application Publication
(10) Pub. No.: US 2006/0060144 A1
(43) Pub. Date: Mar. 23, 2006

(54) Substrate processing apparatus and method using the same

(76) Inventor: Dae-Man Seo, Suwon-si (KR)

Correspondence Address: LEE & MORSE, P.C., 1101 WILSON BOULEVARD, SUITE 2000, ARLINGTON, VA, 22209, US

(21) Appl. No.: 11/149,340

(22) Filed: Jun. 10, 2005

(30) Foreign Application Priority Data
Sep. 20, 2004 (KR) 2004-75148

(51) Int. Cl. C23C 16/00

(52) U.S. Cl. 118/724; 118/719

(57) ABSTRACT

In a substrate processing apparatus used for manufacturing a semiconductor substrate, and a method using the same, the apparatus includes a substrate processing apparatus used for manufacturing a semiconductor substrate includes, a reaction chamber in which a thermal processing process is performed, a heater chamber for providing heat required for the process to the reaction chamber, the heater chamber surrounding the reaction chamber, a housing defining a space in which the reaction chamber and the heater chamber are provided, a heat venting unit for venting heat in the housing, and a controller for controlling the heat venting unit to maintain a temperature of an interior of the reaction chamber within a predetermined range of a process temperature by regulating an amount of thermal atmosphere exhausted through the heat venting unit.

### BACKGROUND OF THE INVENTION

1. Field of the Invention

The present invention relates to an apparatus for manufacturing a semiconductor device and a method using the same. More particularly, the present invention relates to a substrate processing apparatus for performing a thermal treatment process, such as a diffusion or deposition process, and a method of performing the thermal treatment process using the apparatus.

2. Description of the Related Art

A thermal treatment apparatus is used for performing a thermal diffusion process or a deposition process in the manufacture of a semiconductor device. Recently, a vertically arranged thermal treatment apparatus capable of simultaneously performing a thermal treatment process on a plurality of wafers has been used.

A conventional vertically arranged substrate processing apparatus includes a reaction chamber and a heater chamber surrounding the reaction chamber. A stand-by chamber is arranged under the reaction chamber. In operation, wafers are loaded on a boat in the stand-by chamber. A scavenger is arranged around a bottom end, i.e., an entrance, of the reaction chamber and the heater chamber is provided on the scavenger. The scavenger exhausts thermal atmosphere around the entrance of the reaction chamber to the outside. The boat ascends and descends between an interior of the reaction chamber and the stand-by chamber through the entrance of the reaction chamber.

During a deposition process, process conditions, such as process temperature and process pressure, in the reaction chamber significantly affect deposition thickness and deposition uniformity. The actual temperature of the interior of the reaction chamber is changed by various variables other than an amount of heat supplied by the heater chamber. These other variables may include an amount of thermal atmosphere exhausted from the scavenger and a temperature of the thermal atmosphere inside a housing. However, since the conventional vertically arranged thermal treatment apparatus controls only the amount of the heat supplied by the heater chamber, it is difficult to precisely control the process temperature in the reaction chamber.

### SUMMARY OF THE INVENTION

The present invention is therefore directed to a substrate processing apparatus for performing a thermal treatment process and a method using the same, which substantially overcome one or more of the problems due to the limitations and disadvantages of the related art.

It is a feature of an embodiment of the present invention to provide a substrate processing apparatus and a substrate processing method using the same that is capable of correctly maintaining a temperature of an interior of a reaction chamber at a process temperature during a thermal treatment process.

At least one of the above and other features and advantages of the present invention may be realized by providing a substrate processing apparatus used for manufacturing a semiconductor substrate includes, a reaction chamber in which a thermal processing process is performed, a heater chamber for providing heat required for the process to the reaction chamber, the heater chamber surrounding the reaction chamber, a housing defining a space in which the reaction chamber and the heater chamber are provided, a heat venting unit for venting heat in the housing, and a controller for controlling the heat venting unit to maintain a temperature of an interior of the reaction chamber within a predetermined range of a process temperature by regulating an amount of thermal atmosphere exhausted through the heat venting unit.

The heat venting unit may be connected to an interior of the housing, and the heat venting unit may include a heat venting tube for providing a path through which thermal atmosphere is exhausted, a controlling member for controlling the amount of thermal atmosphere exhausted through the heat venting tube, and a measuring member for measuring one selected from the group consisting of an amount of thermal atmosphere exhausted through the heat venting tube and a temperature of the thermal atmosphere, wherein the controller receives a value measured by the measuring member and controls the controlling member in accordance with the measured value.

The measuring member may include a manometer provided in the heat venting tube for measuring a pressure difference between an interior of the heat venting tube and an outside of the housing. Alternatively, the measuring member may include a thermometer for measuring a temperature of a space between the housing and the heater chamber.

The controlling member may include a flow amount controlling member for controlling the amount of thermal atmosphere that flows through the heat venting tube, and wherein the controller is operable to control an opening rate of the flow amount controlling member. The controlling member may include a venting fan for exhausting gas in the housing to the outside of the housing, the venting fan being provided in the venting tube, and the controller is operable to control a rotation speed of the venting fan.

The reaction chamber may have an entrance in a bottom portion thereof, the entrance providing access to a boat in which substrates are loaded, and the heat venting unit may further include a bottom scavenger having a through hole into which the bottom portion of the reaction chamber is inserted in a center thereof and defining a space, the bottom scavenger supporting the heater chamber and being connected to the heat venting tube for venting thermal atmosphere around the entrance of the reaction chamber and thermal atmosphere generated by the heater chamber to an outside through the heat venting tube.

The heat venting unit may further include a top scavenger arranged in the housing, connected to the heat venting tube, and having an adsorbing member with an adsorbing hole through which thermal atmosphere in a space between the housing and the heater chamber flows.

The top scavenger may extend from the adsorbing member onto the heater chamber, and the top scavenger may further include a guide plate for guiding thermal atmosphere in a top portion of the heater chamber to the adsorbing member.

At least one of the above and other features and advantages of the present invention may be realized by providing an apparatus having a stand-by chamber, in which wafers are loaded/unloaded in a boat, which is operable to move up and down, and a processing chamber positioned above the stand-by chamber and having a reaction chamber with an entrance in a bottom end thereof through which the boat moves, and a heater chamber surrounding the reaction chamber, the processing chamber including a housing defining a space in which the reaction chamber and the heater chamber are arranged, a heat venting tube for venting thermal atmosphere in the housing to an outside, a bottom scavenger having a through hole into which the bottom end of the reaction chamber is inserted and defining a space, the bottom scavenger being connected to the heat venting tube for venting thermal atmosphere around the entrance of the reaction chamber and thermal atmosphere generated by the heater chamber to the heat venting tube, a top scavenger positioned in the housing and connected to the heat venting tube, the top scavenger for venting thermal atmosphere in a space between the housing and the heater chamber to the heat venting tube, a controlling member for controlling an amount of thermal atmosphere exhausted through the heat venting tube, a measuring member for measuring one selected from the group consisting of an amount of gas that flows through the heat venting tube and a temperature of the thermal atmosphere in a space between the housing and the heater chamber, and a controller for receiving signals from the measuring member to control the controlling member.

At least one of the above and other features and advantages of the present invention may be realized by providing a method of processing a substrate using a substrate processing apparatus having a heater chamber arranged in a housing and surrounding a reaction chamber in which a thermal treatment process is performed, the method including venting thermal atmosphere around an entrance of the reaction chamber and thermal atmosphere generated by the heater chamber to an outside through a bottom scavenger for supporting the heater chamber and through a heat venting tube connected to the bottom scavenger, measuring one selected from the group consisting of an amount of thermal atmosphere that flows through the heat venting tube and a pressure difference between an interior of the heat venting tube and an outer region, and controlling the amount of thermal atmosphere that flows through the heat venting tube to maintain one of the amount of thermal atmosphere and the pressure difference within a predetermined range.

Controlling the amount of thermal atmosphere that flows through the heat venting tube to maintain one of the amount of the thermal atmosphere and the pressure difference within a predetermined range may include controlling an opening rate of a flow amount controlling member provided in the heat venting tube.

Controlling the amount of thermal atmosphere that flows through the heat venting tube to maintain one of the amount of the thermal atmosphere and the pressure difference within a predetermined range may include controlling a rotation speed of a venting fan for exhausting the thermal atmosphere in the housing to the outside, the venting fan being provided in the heat venting tube.

The substrate processing method may further include venting thermal atmosphere in the space between the housing and the heater chamber to the outside through a top scavenger connected to the heat venting tube.

At least one of the above and other features and advantages of the present invention may be realized by providing a method of processing a substrate using a substrate processing apparatus having a heater chamber arranged in a housing and surrounding a reaction chamber in which a thermal treatment process is performed, the method including venting thermal atmosphere around the entrance of the reaction chamber and thermal atmosphere generated by the heater chamber to an outside through a bottom scavenger for supporting the heater chamber and through a heat venting tube connected to the bottom scavenger, measuring a temperature in a space between the housing and the reaction chamber, and controlling an amount of thermal atmosphere that flows through the heat venting tube to maintain the temperature of the space within a predetermined range.

The method may further include venting the thermal atmosphere in the space between the housing and the heater chamber to the outside through a top scavenger connected to the heat venting tube.

Controlling the amount of thermal atmosphere that flows through the heat venting tube to maintain the temperature of the space within the predetermined range may include controlling an opening rate of a flow control valve provided in the heat venting tube.

Controlling the amount of the thermal atmosphere that flows through the heat venting tube to maintain the temperature of the space within the predetermined range may include controlling a rotation speed of a venting fan for exhausting thermal atmosphere in the housing to the outside, the venting fan being provided in the heat venting tube.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a schematic sectional view of an apparatus for performing a thermal treatment process on a substrate according to an embodiment of the present invention;

FIG. 2 illustrates a perspective view of a top scavenger, a bottom scavenger, and a heater chamber shown in FIG. 1;

FIG. 3 illustrates a schematic view of a flow of thermal atmosphere in a processing chamber;

FIG. 4 illustrates a schematic sectional view of a heat venting unit according to a first embodiment of the present invention;

FIG. 5 illustrates a schematic sectional view of a heat venting unit according to a second embodiment of the present invention;

FIG. 6 is a flowchart sequentially illustrating a method of venting thermal atmosphere according to the first embodiment of the present invention and using the apparatus of FIG. 4; and

FIG. 7 is a flowchart sequentially illustrating a method of venting thermal atmosphere according to the second embodiment of the present invention and using the apparatus of FIG. 5.

### DETAILED DESCRIPTION OF THE INVENTION

Korean Patent Application 2004-75148, filed on Sep. 20, 2004, in the Korean Intellectual Property Office, and entitled: “Apparatus and Method of Processing a Substrate Used for Manufacturing a Semiconductor Substrate,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the shapes and dimensions of elements are exaggerated for clarity of illustration. Like reference numerals refer to like elements throughout.

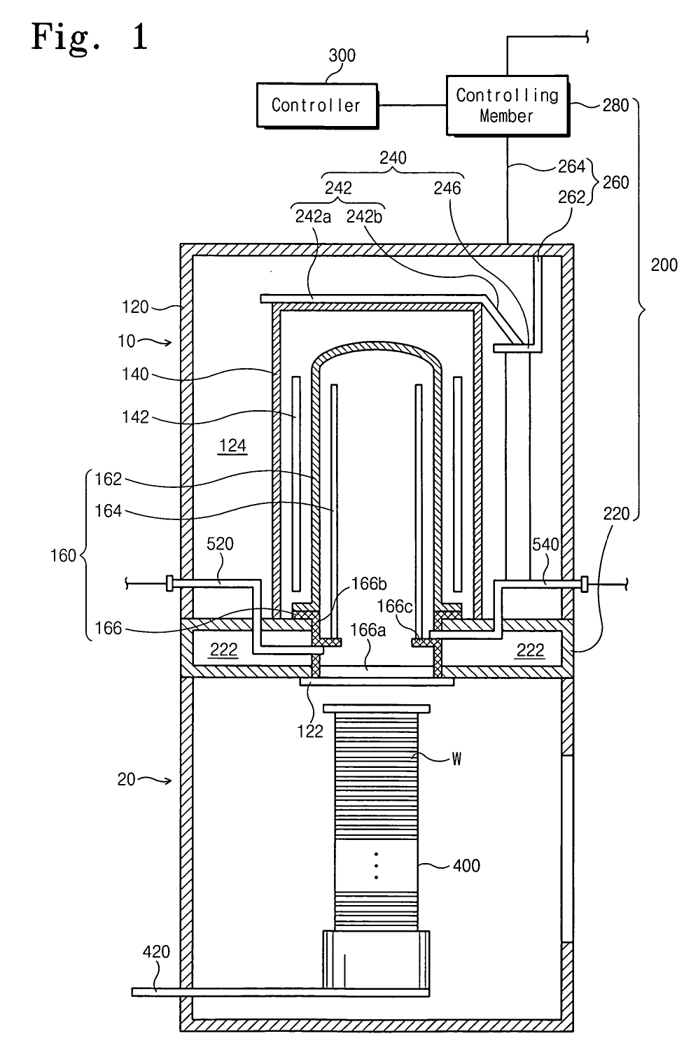

FIG. 1 illustrates a schematic sectional view of an apparatus for performing a thermal treatment process on a substrate according to an embodiment of the present invention. Referring to FIG. 1, the substrate processing apparatus includes a processing chamber 10 and a stand-by chamber 20. The processing chamber 10 and the stand-by chamber 20 are arranged vertically. Wafers W are loaded onto and unloaded from a boat 400 in the stand-by chamber 20. A thermal treatment process, such as a diffusion process or a deposition process, is performed on the wafers W in the processing chamber 10. About fifty to one hundred wafers W, on which processes are performed, may be loaded in the boat 400 at one time. After the wafers W to be processed are loaded into the boat 400 in the stand-by chamber 20, the boat 400 is raised into the processing chamber 10 by a driving portion 420 positioned under the boat 400.

The processing chamber 10 includes a housing 120, a reaction chamber 160, a heater chamber 140, a heat venting unit 200, and a controller 300. The housing 120 forms the external appearance of the processing chamber 10. The reaction chamber 160 and the heater chamber 140 are arranged in the housing 120 to perform the thermal treatment process on the wafers W. The heat venting unit 200 exhausts thermal atmosphere generated in the housing 120 to the outside. The controller 300 controls an amount of thermal atmosphere exhausted by the heat venting unit 200.

The reaction chamber 160 directly provides a space in which the thermal treatment process is performed on the wafers W, and may include an outer tube 162 and an inner tube 164 formed of quartz. The inner tube 164 may be cylindrical having a top portion and a bottom portion thereof open. The outer tube 162, which is provided to surround the inner tube 164, may be cylindrical having only a bottom portion thereof open. The heater chamber 140 for heating the reaction chamber 160 up to the temperature at which reaction gases flowed into the reaction chamber 160 are pyrolyzed and chemical reactions occur is positioned around the outer tube 162. A plate-shaped or coil-shaped heater 142 is loaded in the heater chamber 140.

A flange 166 having a through hole 166a formed in a center thereof is positioned under the inner tube 164 and the outer tube 162. The through-hole 166a functions as an entrance to the reaction chamber 160 through which the boat 400 enters and exits the reaction chamber 160. When the boat 400 enters the reaction chamber 160, a bottom end of the through-hole 166a is closed by a plate 122. The plate 122 may be provided on a bottom end of the boat 400 or may be slidably mounded between the processing chamber 10 and the stand-by chamber 20. A first supporting stand 166b, on which the outer tube 162 is positioned, is formed in a top portion of the flange 166. A second supporting stand 166c, on which the inner tube 164 is positioned, protrudes inward from an inner wall of the flange 166.

A reaction gas inflow line 520 through which reaction gases are supplied and a purge gas inflow line (not shown) through which a purge gas, e.g., nitrogen, is supplied in order to prevent a natural oxide film from forming on the wafers, are connected to one side of the flange 166. A venting line 540 having a pump (not shown) is connected to the other side of the flange 166. During each process, the interior of the reaction chamber 160 is maintained to a predetermined vacuum degree by the pump and reaction by-products in the reaction chamber 160 are exhausted through the venting line 540.

The above-described structure of the reaction chamber 160 is only exemplary. For example, the reaction chamber 160 may be provided by a single tube. Also, a nozzle of the reaction gas inflow line 520 or the purge gas inflow line may be arranged in a top end of the reaction chamber 160. Further, the venting line may be connected to a bottom end of the reaction chamber 160.

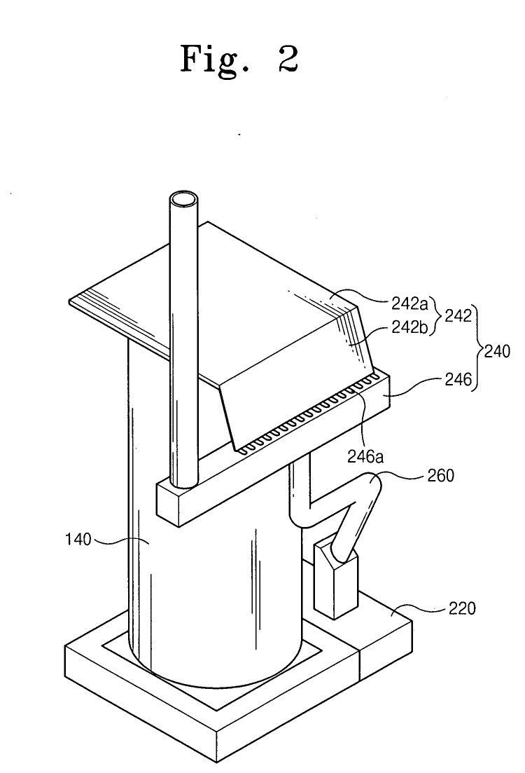

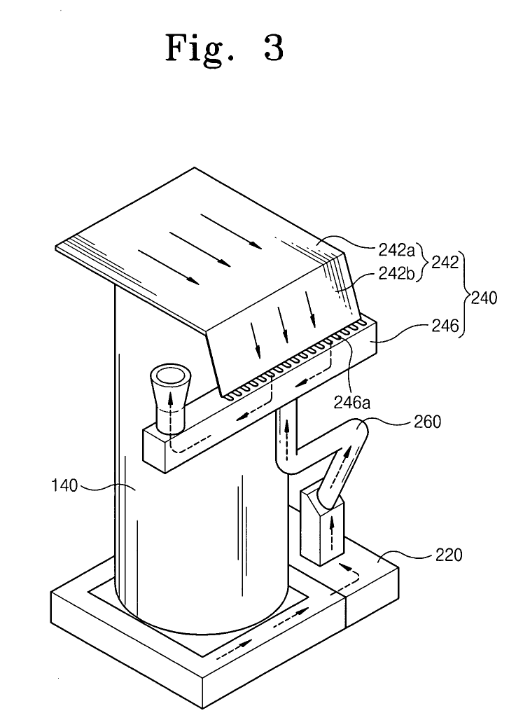

FIG. 2 illustrates a perspective view of a top scavenger, a bottom scavenger, and a heater chamber shown in FIG. 1. FIG. 3 illustrates a schematic view of a flow of thermal atmosphere in a processing chamber.

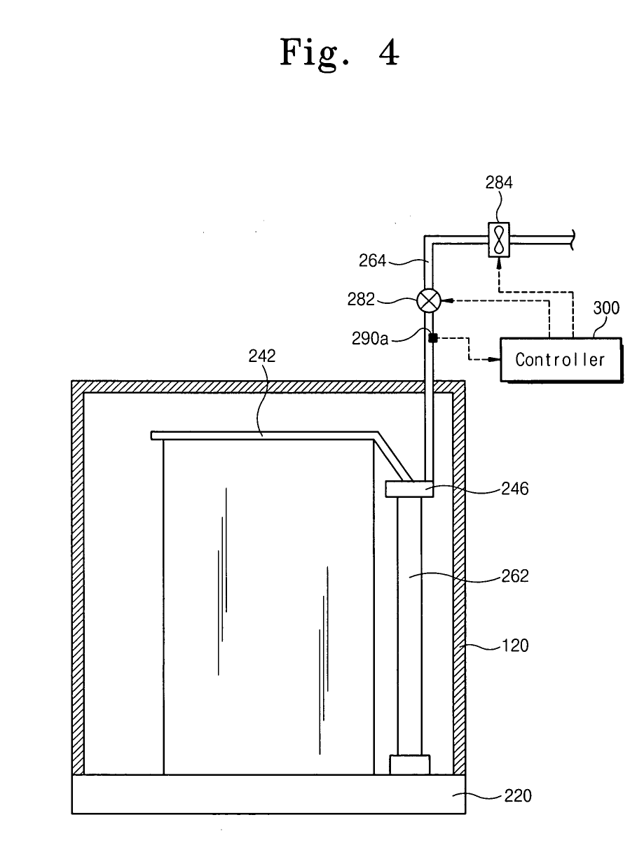

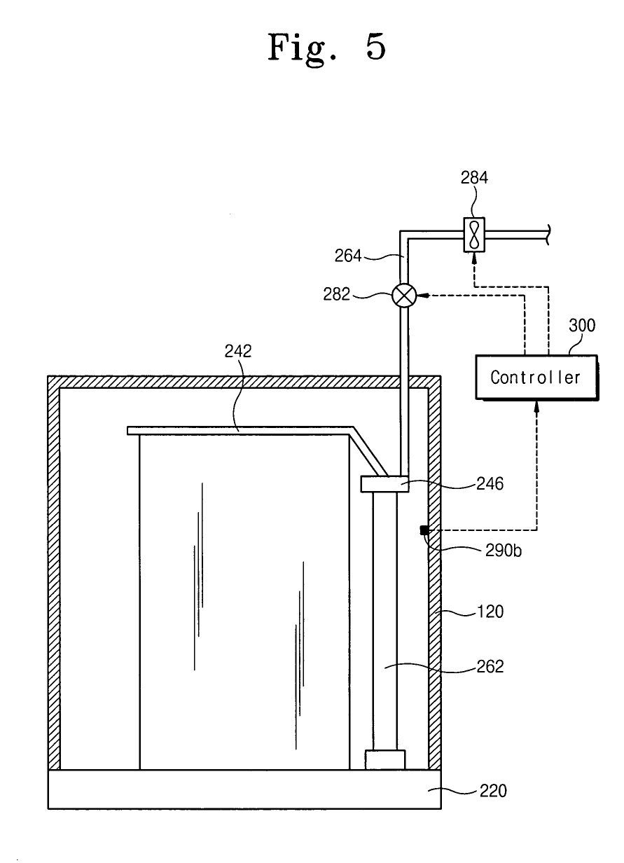

With reference to FIGS. 2 through 4, thermal atmosphere in the housing 120 is exhausted to the outside through the heat venting unit 200. The heat venting unit 200 includes a bottom scavenger 220, a top scavenger 240, a heat venting tube 260, a measuring member, e.g., a manometer (290a of FIG. 4) or a thermometer (290b of FIG. 5), and a controlling member 280. The bottom scavenger 220 surrounds the flange 166 and further defines the through hole 166a into which the flange 166 is inserted in a center thereof. The bottom scavenger 220 supports the above-described heater chamber 140 and exhausts thermal atmosphere around the entrance of the reaction chamber 160 and thermal atmosphere generated by the heater chamber 140 to the outside. The bottom scavenger 220 is formed of a material that facilitates thermal transmission, e.g., stainless steel. The bottom scavenger 220 may be cylindrical such that a space 222 into which the atmosphere flows is formed therein. The atmosphere can flow into the space 222 in the bottom scavenger 220 through the gaps between structures. An additional aperture, through which the atmosphere may flow, may be selectively provided in the bottom scavenger 220.

The space 222 in the bottom scavenger 220 is connected to the heat venting tube 260. The heat venting tube 260 is combined with the bottom scavenger 220 and extends out of the processing chamber 10. The heat venting tube 260 may be formed of a plurality of tubes. The heat venting tube 260 includes an inner tube 262 positioned in the processing chamber 10 and an outer tube 264 positioned outside of the processing chamber 10.

With reference to FIGS. 4 and 5, which illustrate first and second embodiments of the heat venting unit 200 according to the present invention, a flow amount controlling valve 282, e.g., a flow control valve, for controlling an amount of thermal atmosphere that flows inside the outer tube 264 or a venting fan 284 for forcibly exhausting thermal atmosphere in the processing chamber 10 to the outside may be provided in the outer tube 264. The flow control valve 282 may be electrically controllable. An opening rate of the flow control valve 282 and a rotation speed of the venting fan 284 are controlled by the controller 300.

The amount of thermal atmosphere exhausted from the processing chamber 10 through the heat venting unit 200 affects the temperature of the interior of the reaction chamber 160. For example, when a large amount of thermal atmosphere is exhausted through the heat venting tube 260, the temperature of the interior of the reaction chamber 160 decreases. When a small amount of thermal atmosphere is exhausted, the temperature of the interior of the reaction chamber 160 increases.

Referring back to FIGS. 2 through 4, the atmosphere in a space 124 between the housing 120 and the heater chamber 140 is heated by the heater chamber 140. When the temperature of the atmosphere in the space 124 is high, heat is not continuously emitted from the heater chamber 140, which affects the temperature of the interior of the reaction chamber 160. The top scavenger 240 for venting thermal atmosphere in the space 124 to the outside is provided on the heater chamber 140 in the housing 120.

The top scavenger 240 includes an adsorbing member 246 and a guide plate 242. The adsorbing member 246 is inserted into the inner tube 262 of the heat venting tube 260. The adsorbing member 246 may be rectangular parallelepiped and may have adsorbing holes 246a on a top surface thereof for adsorbing thermal atmosphere. The thermal atmosphere adsorbed through the adsorbing holes 246a is exhausted to the outside through the same venting path as the thermal atmosphere exhausted through the top scavenger 240, as may be seen in FIG. 3. In general, the hot thermal atmosphere is primarily positioned in a top portion of the housing 120. The guide plate 242 guides the thermal atmosphere positioned in the top portion of the housing 120 to the adsorbing member 246. The guide plate 242 has a substantially flat rectangular top plate 242a positioned on the heater member 140 and a rectangular inclined plate 242b that extends from the top plate 242a to the adsorbing holes 246a of the adsorbing member 246 positioned below the top plate 242a and is inclined at a predetermined angle. The guide plate 242 is formed of a material that facilitates thermal transmission, e.g., stainless steel, to facilitate inducing thermal atmosphere to the adsorbing member 246. In the processing chamber 10, the thermal atmosphere is exhausted to the outside through the heat venting tube 260, as illustrated in FIG. 3.

According to an embodiment of the present invention, the heat venting unit 200 controls the amount of the thermal atmosphere exhausted through the heat venting tube 260 to maintain the temperature of the reaction chamber 160 in a range of a process temperature. FIG. 4 illustrates the heat venting unit 200 according to a first embodiment of the present invention. Referring to FIG. 4, in the heat venting unit 200 according to the first embodiment of the present invention, the measuring member is the manometer 290a. The manometer 290a measures an amount of thermal atmosphere, i.e., an amount of gas, that flows through the heat venting tube 260. The heat venting unit 200 additionally includes the controlling member 280 for controlling the amount of thermal atmosphere exhausted. The controlling member 280 may be the flow control valve 282 or the venting fan 284, as described above. In the first embodiment, both the flow control valve 282 and the manometer 290a are provided in the outer tube 264, however, the manometer 290a is provided in a position closer to the processing chamber 10 than the flow control valve 282. The manometer 290a measures a pressure difference in the heat venting tube 260 in front of and beyond the position in which the flow control valve 282 is provided. When the pressure is maintained at a uniform differential pressure as compared with the pressure of an outer region, e.g., beyond the position of the flow control valve 282, the manometer 290a can measure the pressure difference between the pressure of the interior of the heat venting tube 260 and the pressure of the outer region. In general, since an interior of a clean room (not shown) is maintained to have a uniform differential pressure as compared with an outside pressure during semiconductor manufacturing processes, according to an embodiment of the present invention, the outer region may be the interior of the clean room, i.e., outside of the housing, or outside of the clean room. When the differential pressure is large, the amount of the thermal atmosphere exhausted through the heat venting tube 260 increases and the temperature of the reaction chamber 160 decreases. Therefore, in order to control the amount of thermal atmosphere exhausted through the heat venting tube 260, the controller 300 controls an opening rate of the flow control valve 282 or a rotation speed of the venting fan 284 in accordance with a magnitude of the differential pressure. For example, when the measured differential pressure exceeds a predetermined range, the controller 300 reduces the opening rate of the flow control valve 282 or reduces the rotation speed of the venting fan 284 to reduce the amount of thermal atmosphere exhausted to maintain the differential pressure within the predetermined range. In the alternative, when the differential pressure is less than the predetermined range, the controller 300 increases the opening rate of the flow control valve 282 or increases the rotation speed of the venting fan 284 to increase the amount of thermal atmosphere exhausted to maintain the differential pressure within the predetermined range.

FIG. 5 illustrates a heat venting unit 200 according to the second embodiment of the present invention. In the second embodiment of the present invention, the measuring member of the heat venting unit 200 is provided by a thermometer 290b, which is provided on an inner wall of the housing 120, for measuring a temperature of thermal atmosphere in the space 124 between the housing 120 and the heater chamber 140. The heat venting unit 200 further includes the controlling member 280 for controlling an amount of thermal atmosphere exhausted through the heat venting tube 260. As described in connection with the first embodiment, the flow control valve 282 or the venting fan 284 may be used as the controlling member 280. The temperature of the interior of the space 124 between the housing 120 and the heater chamber 140 is maintained in proportion to the process temperature of the interior of the reaction chamber 160. In accordance with each process, a preferable temperature of the interior of the space 124 between the housing 120 and the heater chamber 140 is experimentally measured. Subsequently, a preferable temperature range, i.e., the predetermined temperature range, of the interior of the space 124 between the housing 120 and the heater chamber 140 is established and the predetermined preferable temperature range is stored in the controller 300. During each process, the temperature of the interior of the space 124 between the housing 120 and the heater chamber 140 is measured by the thermometer 290b. When the measured temperature deviates from the predetermined temperature range, the controller 300 controls the amount of thermal atmosphere exhausted to regulate the temperature of the interior of the space 124. For example, when the temperature measured during each process is lower than the range of the set temperature, the temperature of the interior of the reaction chamber 160 is lower than the process temperature. In this case, the controller 300 reduces the opening rate of the flow control valve 282 or reduces the rotation speed of the venting fan 284 to reduce the amount of thermal atmosphere exhausted to increase and then maintain the temperature of the interior of the space 124 between the housing 120 and the heater chamber 140 in the range of the predetermined temperature. In the alternative, when the temperature measured during each process is higher than the range of the predetermined temperature, the temperature of the interior of the reaction chamber 160 is higher than the process temperature. In this case, the controller 300 increases the opening rate of the flow control valve 282 or increases the rotation speed of the venting fan 284 to increase the amount of thermal atmosphere exhausted to reduce and then maintain the temperature of the interior of the space 124 between the housing 120 and the heater chamber 140 in the range of the predetermined temperature.

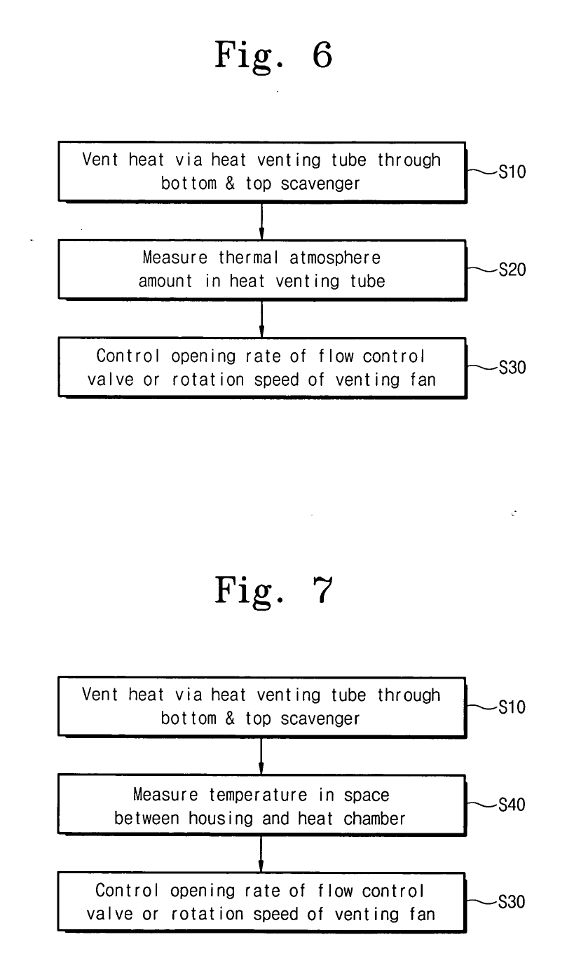

A method of processing a substrate using the apparatus according to the embodiments of the present invention will now be described. FIG. 6 is a flowchart sequentially illustrating the method of processing a substrate using the apparatus according to the first embodiment of the present invention shown in FIG. 4. FIG. 7 is a flowchart sequentially illustrating the method of processing a substrate using the apparatus according to the second embodiment of the present invention shown in FIG. 5.

Initially, the boat 400, in which the wafers W are loaded, enters the reaction chamber 160 and the entrance of the reaction chamber 160 is closed. During each process, in step S10, the heat generated around the entrance of the reaction chamber 160 and the heater chamber is exhausted to the heat venting tube 260 through the bottom scavenger 220 and the thermal atmosphere in the space 124 between the housing 120 and the heater chamber 140 is exhausted to the heat venting tube 260 through the top scavenger 240. In the first embodiment, in step S20, the amount of the thermal atmosphere exhausted through the heat venting tube 260 is measured by the manometer 290a. In the second embodiment, in step S40, the temperature of the atmosphere in the space 124 between the housing 120 and the heater chamber 140 is measured by the thermometer 290b.

After performing the above measurements in steps S20 and S40, respectively, both the first and second embodiments proceed to step S30. In step S30, the controller 300 controls the opening rate of the flow control valve 282 or the rotation speed of the venting fan 284 such that the amount of the thermal atmosphere exhausted through the heat venting tube 260 is within a predetermined range.

According to an embodiment of the present invention, during a thermal treatment process, an amount of thermal atmosphere exhausted from the processing chamber may be controlled to maintain a temperature of the interior of the reaction chamber at the process temperature.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A substrate processing apparatus used for manufacturing a semiconductor substrate, comprising:
a reaction chamber in which a thermal processing process is performed;
a heater chamber for providing heat required for the process to the reaction chamber, the heater chamber surrounding the reaction chamber;
a housing defining a space in which the reaction chamber and the heater chamber are provided;
a heat venting unit for venting heat in the housing; and
a controller for controlling the heat venting unit to maintain a temperature of an interior of the reaction chamber within a predetermined range of a process temperature by regulating an amount of thermal atmosphere exhausted through the heat venting unit.

2. The substrate processing apparatus as claimed in claim 1, wherein the heat venting unit is connected to an interior of the housing, the heat venting unit comprising:
a heat venting tube for providing a path through which thermal atmosphere is exhausted;
a controlling member for controlling the amount of thermal atmosphere exhausted through the heat venting tube; and
a measuring member for measuring one selected from the group consisting of an amount of thermal atmosphere exhausted through the heat venting tube and a temperature of the thermal atmosphere,
wherein the controller receives a value measured by the measuring member and controls the controlling member in accordance with the measured value.

3. The substrate processing apparatus as claimed in claim 2, wherein the measuring member comprises a manometer provided in the heat venting tube for measuring a pressure difference between an interior of the heat venting tube and an outside of the housing.

4. The substrate processing apparatus as claimed in claim 2, wherein the measuring member comprises a thermometer for measuring a temperature of a space between the housing and the heater chamber.

5. The substrate processing apparatus as claimed in claim 2,
wherein the controlling member comprises a flow amount controlling member for controlling the amount of thermal atmosphere that flows through the heat venting tube, and wherein the controller is operable to control an opening rate of the flow amount controlling member.

6. The substrate processing apparatus as claimed in claim 2,
wherein the controlling member comprises a venting fan for exhausting gas in the housing to the outside of the housing, the venting fan being provided in the venting tube, and the controller is operable to control a rotation speed of the venting fan.

7. The substrate processing apparatus as claimed in claim 2,
wherein the reaction chamber has an entrance in a bottom portion thereof, the entrance providing access to a boat in which substrates are loaded, and wherein the heat venting unit further comprises:
a bottom scavenger having a through hole into which the bottom portion of the reaction chamber is inserted in a center thereof and defining a space, the bottom scavenger supporting the heater chamber and being connected to the heat venting tube for venting thermal atmosphere around the entrance of the reaction chamber and thermal atmosphere generated by the heater chamber to an outside through the heat venting tube.

8. The substrate processing apparatus as claimed in claim 2, wherein the heat venting unit further comprises a top scavenger arranged in the housing, connected to the heat venting tube, and having an adsorbing member with an adsorbing hole through which thermal atmosphere in a space between the housing and the heater chamber flows.

9. The substrate processing apparatus as claimed in claim 8, wherein the top scavenger extends from the adsorbing member onto the heater chamber, the top scavenger further comprising a guide plate for guiding thermal atmosphere in a top portion of the heater chamber to the adsorbing member.

10. An apparatus having a stand-by chamber, in which wafers are loaded/unloaded in a boat, which is operable to move up and down, and a processing chamber positioned above the stand-by chamber and having a reaction chamber with an entrance in a bottom end thereof through which the boat moves, and a heater chamber surrounding the reaction chamber, the processing chamber comprising:
a housing defining a space in which the reaction chamber and the heater chamber are arranged;
a heat venting tube for venting thermal atmosphere in the housing to an outside;
a bottom scavenger having a through hole into which the bottom end of the reaction chamber is inserted and defining a space, the bottom scavenger being connected to the heat venting tube for venting thermal atmosphere around the entrance of the reaction chamber and thermal atmosphere generated by the heater chamber to the heat venting tube;
a top scavenger positioned in the housing and connected to the heat venting tube, the top scavenger for venting thermal atmosphere in a space between the housing and the heater chamber to the heat venting tube;
a controlling member for controlling an amount of thermal atmosphere exhausted through the heat venting tube;
a measuring member for measuring one selected from the group consisting of an amount of gas that flows through the heat venting tube and a temperature of the thermal atmosphere in a space between the housing and the heater chamber; and
a controller for receiving signals from the measuring member to control the controlling member.

11. A method of processing a substrate using a substrate processing apparatus having a heater chamber arranged in a housing and surrounding a reaction chamber in which a thermal treatment process is performed, the method comprising:
venting thermal atmosphere around an entrance of the reaction chamber and thermal atmosphere generated by the heater chamber to an outside through a bottom scavenger for supporting the heater chamber and through a heat venting tube connected to the bottom scavenger;
measuring one selected from the group consisting of an amount of thermal atmosphere that flows through the heat venting tube and a pressure difference between an interior of the heat venting tube and an outer region; and
controlling the amount of thermal atmosphere that flows through the heat venting tube to maintain one of the amount of thermal atmosphere and the pressure difference within a predetermined range.

12. The method as claimed in claim 11, wherein controlling the amount of thermal atmosphere that flows through the heat venting tube to maintain one of the amount of the thermal atmosphere and the pressure difference within a predetermined range comprises controlling an opening rate of a flow amount controlling member provided in the heat venting tube.

13. The method as claimed in claim 11, wherein controlling the amount of thermal atmosphere that flows through the heat venting tube to maintain one of the amount of the thermal atmosphere and the pressure difference within a predetermined range comprises controlling a rotation speed of a venting fan for exhausting the thermal atmosphere in the housing to the outside, the venting fan being provided in the heat venting tube.

14. The method as claimed in claim 11, wherein the substrate processing method further comprises venting thermal atmosphere in the space between the housing and the heater chamber to the outside through a top scavenger connected to the heat venting tube.

15. A method of processing a substrate using a substrate processing apparatus having a heater chamber arranged in a housing and surrounding a reaction chamber in which a thermal treatment process is performed, the method comprising:
venting thermal atmosphere around the entrance of the reaction chamber and thermal atmosphere generated by the heater chamber to an outside through a bottom scavenger for supporting the heater chamber and through a heat venting tube connected to the bottom scavenger;
measuring a temperature in a space between the housing and the reaction chamber; and
controlling an amount of thermal atmosphere that flows through the heat venting tube to maintain the temperature of the space within a predetermined range.

16. The method as claimed in claim 15, wherein the substrate processing method further comprises venting the thermal atmosphere in the space between the housing and the heater chamber to the outside through a top scavenger connected to the heat venting tube.

17. The substrate processing method as claimed in claim 15, wherein controlling the amount of thermal atmosphere that flows through the heat venting tube to maintain the temperature of the space within the predetermined range comprises controlling an opening rate of a flow control valve provided in the heat venting tube.

18. The substrate processing method as claimed in claim 15, wherein controlling the amount of the thermal atmosphere that flows through the heat venting tube to maintain the temperature of the space within the predetermined range comprises controlling a rotation speed of a venting fan for exhausting thermal atmosphere in the housing to the outside, the venting fan being provided in the heat venting tube.
